(19) United States
(12) Patent Application Publication
(10) Pub. No.: US 2025/0029828 A1
(43) Pub. Date: Jan. 23, 2025

(54) METHOD OF PROCESSING WORKPIECE

(71) Applicant: DISCO CORPORATION, Tokyo (JP)

(72) Inventor: Kokichi MINATO, Tokyo (JP)

(21) Appl. No.: 18/765,518

(22) Filed: Jul. 8, 2024

(30) Foreign Application Priority Data
Jul. 21, 2023 (JP) 2023-118958

(51) Int. Cl. H01L 21/02; B26D 3/02

(52) U.S. Cl. CPC H01L 21/02021; B26D 3/02

(57) ABSTRACT

A method of processing a workpiece having a beveled edge on its outer circumferential portion to cut off a part of the outer circumferential portion includes placing the workpiece on a holding surface of a chuck table that is rotatable about a table rotation axis, forcing a cutting edge portion of an annular cutting blade to cut into the beveled edge while the cutting blade is rotating about a blade rotation axis, and rotating the chuck table about the table rotation axis, thereby cutting into the beveled edge with the cutting blade to cut off a part of the workpiece. While the cutting blade is cutting into the beveled edge, the table rotation axis and the blade rotation axis do not intersect with each other.

### BACKGROUND OF THE INVENTION

### Field of the Invention

The present invention relates to a method of processing a workpiece such as a semiconductor wafer having a beveled edge on its outer circumferential portion by performing an edge trimming process on the outer circumferential portion of the workpiece to thereby cut off a part of the outer circumferential portion.

### Description of the Related Art

According to a process of fabricating device chips to be used in electronic appliances such as cellular phones and personal computers, a plurality of intersecting projected dicing lines also known as streets are established on a face side of a wafer made of a semiconductor material. Then, a plurality of devices such as integrated circuits (ICs) or large-scale-integration (LSI) circuits are constructed in respective areas demarcated on the face side of the wafer. Thereafter, the wafer is ground on its reverse side to thin itself down, and the wafer is divided along the projected dicing lines into individual device chips. Before the wafer is ground, the outer circumferential portion of the wafer is processed to form a beveled edge thereon for preventing the outer circumferential portion from being chipped or otherwise damaged. The outer circumferential portion of the wafer with the beveled edge is of an arcuate cross-sectional shape extending from the face side to the reverse side of the wafer.

When the wafer with the beveled edge on the outer circumferential portion thereof is ground on the reverse side to thin itself down, the reverse side as it is progressively ground flatwise causes its outer circumferential edge to eat away the arcuate cross-sectional shape of the beveled edge, turning it into a knife-edge shape, i.e., a sharp edge. The knife-edge shape is liable to allow the beveled edge to chip easily. One solution to this problem has been to perform an edge trimming process on the outer circumferential portion of a wafer with a beveled edge by causing an annular cutting blade to cut into the outer circumferential portion of the wafer to remove at least a part of the beveled edge before the wafer is ground (see, for example, JP 2000-173961A, JP 2004-207459A, JP 2016-127098A, and JP 2020-40181A). When the wafer is ground after the edge trimming process, no knife-edge shape is formed on the outer circumferential portion of the wafer. In the edge trimming process, the position of the wafer, which is of a circular planar shape, is adjusted with respect to the cutting blade such that a rotational axis of the cutting blade, i.e., the central cutting blade axis, extends perpendicularly to a line tangential to the wafer at an outer circumferential position thereof where the cutting blade cuts into the wafer. At this time, the center of the wafer is aligned with the central cutting blade axis. The edge trimming process is carried out when the cutting blade cuts into the wafer while the wafer is being rotated about its center.

### SUMMARY OF THE INVENTION

When the edge trimming process is performed on the wafer, the outer circumferential portion of the wafer is turned into a terrace surface parallel to the face side of the wafer and a precipitous wall surface rising sharply from an inner circumferential end of the terrace surface. The terrace surface and the wall surface tend to have abrasive grain marks represented by recess and projection surface irregularities left by abrasive grains contained in the cutting edge of the cutting blade. In addition, the face side of the wafer is liable to break into chippings. When the wafer is ground after the edge trimming process, cracks are brought about in the wafer from the abrasive grain marks and the chippings due to impact. The cracks are likely to develop in the wafer and fragments caused by the abrasive grain marks are apt to be separated and then deposited on the wafer. Furthermore, swarf produced from the wafer when the wafer is ground may find its way into the abrasive grain marks and remain trapped in the wafer. If the above difficulties occur, then when the wafer is subsequently divided into device chips, the device chips are highly likely to become poor in quality, or the number of normal device chips fabricated from the wafer is reduced to the extent that the efficiency with which to fabricate device chips from the wafer is unduly lowered.

It is therefore an object of the present invention to provide a method of processing a workpiece to perform a high-quality edge trimming process on the workpiece.

In accordance with an aspect of the present invention, there is provided a method of processing a workpiece having a beveled edge on its outer circumferential portion by performing an edge trimming process on the outer circumferential portion thereby to cut off a part of the outer circumferential portion, including a holding step of placing the workpiece on a holding surface of a chuck table that is rotatable about a table rotation axis perpendicular to the holding surface and holding the workpiece on the chuck table, and after the holding step, an incising step of forcing a cutting edge portion of an annular cutting blade to cut into the beveled edge of the workpiece while the cutting blade is rotating about a blade rotation axis, and causing the chuck table to make at least one revolution about the table rotation axis, thereby cutting into the beveled edge with the cutting blade along an entire outer circumference of the workpiece to cut off a part of the workpiece. While the cutting blade is cutting into the beveled edge of the workpiece in the incising step, the table rotation axis and the blade rotation axis do not intersect with each other.

Preferably, while the cutting blade is cutting into the beveled edge of the workpiece in the incising step, an angle formed between a straight line interconnecting the table rotation axis and a center of the cutting edge portion of the cutting blade on a plane lying parallel to the holding surface of the chuck table and including the center of the cutting edge portion of the cutting blade, and the blade rotation axis is in a range from 5° to 175°.

In the method of processing a workpiece according to the aspect of the invention, the incising step is carried out to force the cutting edge portion of the cutting blade to cut into the beveled edge of the workpiece while rotating the annular cutting blade about the blade rotation axis. The chuck table is rotated to make at least one revolution about the table rotation axis, causing the cutting blade to cut into the beveled edge and remove a part of the workpiece. According to a conventional edge trimming process, while causing the cutting blade to cut into the beveled edge, the table rotation axis and the blade rotation axis intersect with each other. At the incising position where the cutting edge portion of the cutting blade cuts into the workpiece, the direction along which the workpiece moves and the direction along which the cutting edge portion moves coincide with each other. Therefore, it is considered that the cutting blade is liable to leave sharp abrasive grain marks on the workpiece.

In the method of processing a workpiece according to the aspect of the invention, by contrast, while causing the cutting blade to cut into the beveled edge, the table rotation axis and the blade rotation axis do not intersect with each other. At the incising position where the cutting edge portion of the cutting blade cuts into the workpiece, the direction along which the workpiece moves and the direction along which the cutting edge portion moves do not coincide with each other. In this case, even though abrasive grain marks are formed on the workpiece by the cutting edge portion of the cutting blade, the abrasive grain marks are immediately polished off by the cutting edge portion, planarizing the workpiece, i.e., improving the surface roughness of the workpiece. Moreover, a terrace surface and a wall surface that are formed on the workpiece in the edge trimming process are joined to each other by a curved surface of rounded shape, and the curved surface reinforces the terrace surface and the wall surface to make the workpiece less likely to give rise to cracks and chippings. The quality of device chips fabricated from the workpiece when the workpiece is finally divided becomes higher, or the number of normal device chips fabricated from the workpiece grows, thereby increasing the efficiency with which the device chips are fabricated from the workpiece.

Consequently, according to the aspect of the invention, there is provided a method of processing a workpiece to perform a high-quality edge trimming process on the workpiece.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically illustrating a wafer as a workpiece;

FIG. 2 is a perspective view schematically illustrating a cutting apparatus;

FIG. 3 is a plan view schematically illustrating a positional relation between a chuck table and a cutting unit at the time a conventional edge trimming process is carried out;

FIG. 4 is a side elevational view schematically illustrating the manner in which the conventional edge trimming process is carried out;

FIG. 5 is a plan view schematically illustrating a positional relation between the chuck table and the cutting unit at the time an incising step according to an example is carried out;

FIG. 6 is a side elevational view schematically illustrating the manner in which the incising step according to the example is carried out;

FIG. 7 is a plan view schematically illustrating a positional relation between the chuck table and the cutting unit at the time an incising step according to another example is carried out;

FIG. 8 is a side elevational view schematically illustrating the manner in which the incising step according to the other example is carried out;

FIG. 9 is a perspective view schematically illustrating a grinding apparatus;

FIG. 10 is a side elevational view schematically illustrating the manner in which the workpiece is ground by the grinding apparatus; and

FIG. 11 a flowchart of the sequence of steps of a method of processing a workpiece according to an embodiment of the present invention.

### DETAILED DESCRIPTION OF THE PREFERRED EMBODIMENT

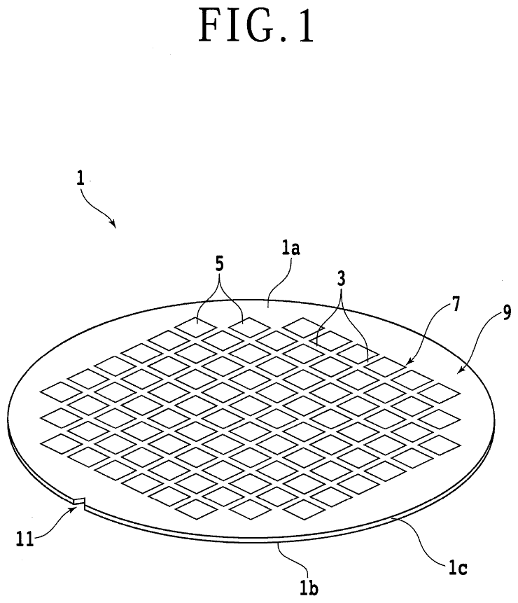

A method of processing a workpiece according to a preferred embodiment of the present invention will be described below with reference to the accompanying drawings. First, the workpiece to be processed by the method according to the present embodiment will be described below. FIG. 1 illustrates the workpiece, denoted by 1, in perspective. The workpiece 1 includes a wafer shaped as a circular plate made of silicon (Si), silicon carbide (SiC), gallium nitride (GaN), gallium arsenide (GaAs), or other semiconductor materials. The workpiece 1 has a diameter in an approximate range from 6to 12 inches and a thickness in an approximate range from 400 to 2000 μm. However, the workpiece 1 is not limited to these diameters and thicknesses. The workpiece 1 has a face side 1a including a plurality of areas demarcated by a grid of projected dicing lines 3 established thereon. A plurality of devices 5 such as ICs or LSI circuits are constructed respectively in the demarcated areas of the face side 1a. The devices 5 are present in a device region 7 on the face side 1a, which is surrounded by an outer circumferential extra region 9. The workpiece 1 will be ground on a reverse side 1b thereof that is opposite the face side 1a to thin itself down, and thereafter will be divided along the projected dicing lines 3 into individual device chips having the respective devices 5.

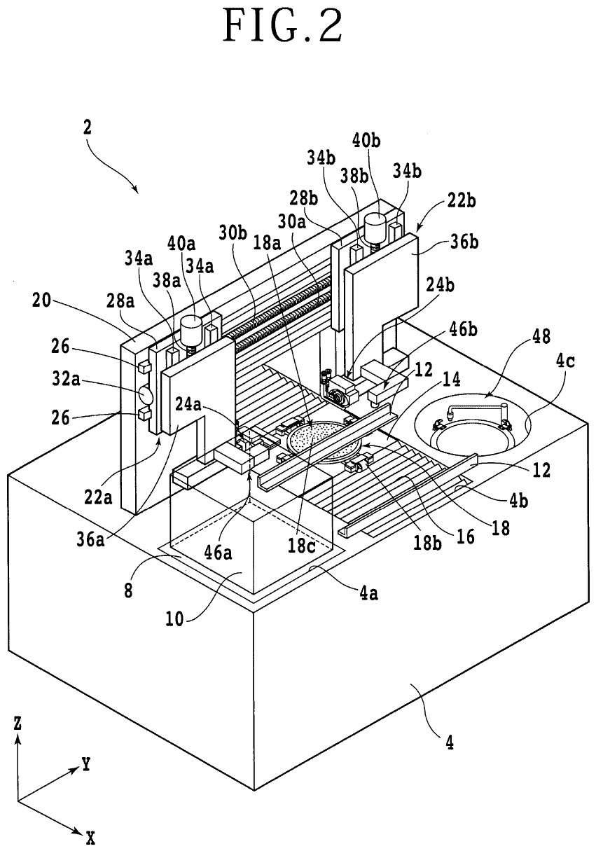

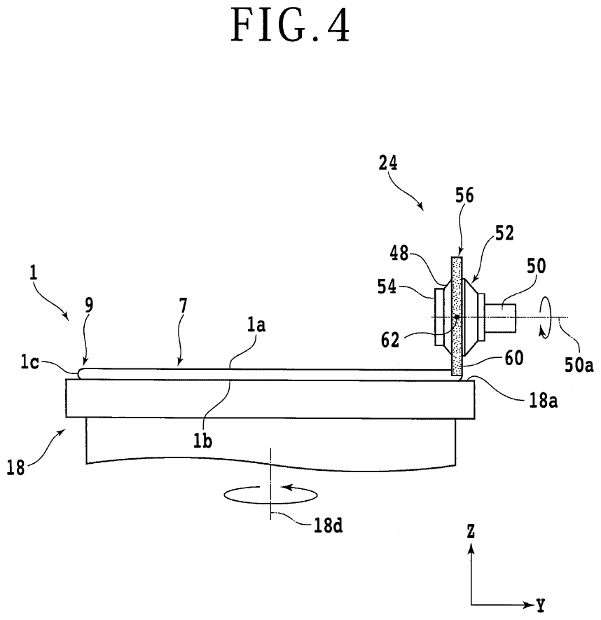

In order to prevent the workpiece 1 from being chipped or cracked in its outer edge, a beveled edge (see FIG. 4) is formed on an outer circumferential portion 1c of the workpiece 1 by cutting off its angular corners. The beveled edge has an arcuate cross-sectional shape extending from the face side 1a to the reverse side 1b of the workpiece 1. The workpiece 1 has a recess 11 defined in the outer circumferential portion 1c, called a “notch” indicative of the crystal orientation of the material of the workpiece 1. If the workpiece 1 with the beveled edge on the outer circumferential portion 1c were ground on its reverse side 1b to thin itself down, then the reverse side 1b as it would be progressively ground flatwise causes its outer circumferential edge to eat away the arcuate cross-sectional shape of the beveled edge, turning it into a knife-edge shape. The knife-edge shape would be liable to allow the outer circumferential portion 1c to chip easily. To avoid forming the knife-edge shape, an edge trimming process is performed on the workpiece 1 to cut the outer circumferential portion 1c to remove the beveled edge before the workpiece 1 is ground. FIG. 2 schematically illustrates, in perspective, a cutting apparatus 2 to be used in the edge trimming process.

The workpiece 1 to be cut on the cutting apparatus 2 is introduced into the cutting apparatus 2 as included in a frame unit where the workpiece 1 is combined with, for example, an annular frame, not depicted, having an opening larger in diameter than the workpiece 1 and a tape, not depicted, affixed to the annular frame in closing relation to the opening and also to the reverse side 1b of the workpiece 1. The workpiece 1 thus combined with the annular frame and the tape can easily be handled as the frame unit. However, the annular frame and the tape are omitted from illustration in the drawings for illustrative purposes.

The cutting apparatus 2 to be used in the edge trimming process will be described in detail below with reference to FIG. 2. In FIG. 2 and other figures, the cutting apparatus 2 is illustrated in reference to a three-dimensional XYZ coordinate system having an X-axis indicated by an arrow X, a Y-axis indicated by an arrow Y, and a Z-axis indicated by an arrow Z. The X-axis and the Y-axis lie horizontally and extend perpendicularly to each other. The Z-axis extends vertically and perpendicularly to the X-axis and the Y-axis. Structural and operational details of various components of the cutting apparatus 2 will be described below in relation to the X-axis, the Y-axis, and the Z-axis.

The cutting apparatus 2 includes a foundation base 4 that supports various components of the cutting apparatus 2 as described below. The foundation base 4 has an upwardly open square opening 4a defined in a front corner thereof. A cassette support table 8 that is vertically movable by a lifting and lowering mechanism, not depicted, is housed in the opening 4a. The cassette support table 8 supports thereon a cassette 10 housing therein a plurality of workpieces 1 each included in a frame unit. In FIG. 2, only the contour of the cassette 10 is depicted for illustrative purposes. The foundation base 4 also has an upwardly open rectangular opening 4b defined therein that extends longitudinally along the X-axis (forward and rearward directions, processing-feed direction) laterally of the cassette support table 8. Forward and rearward directions or processing-feed directions to be referred to below extend along the X-axis. The opening 4b houses therein a ball-screw-type X-axis moving mechanism, not depicted, a table cover 14 covering an upper portion of the X-axis moving mechanism, and a bellows-shaped dust-proof, drip-proof cover 16. The X-axis moving mechanism includes an X-axis movable table, not depicted, covered with the table cover 14 and moves the X-axis movable table along the X-axis.

A chuck table 18 is mounted on an upper surface of the X-axis movable table and has a holding surface 18a exposed upwardly from the table cover 14. The chuck table 18 has a function to hold under suction the workpiece 1 that has been placed on the upwardly exposed holding surface 18a. The chuck table 18 is operatively coupled to a rotary actuator, not depicted, such an electric motor, and is rotatable thereby about a central axis generally parallel to the Z-axis, i.e., vertical directions. The chuck table 18 includes a porous member 18c having the same diameter as the workpiece 1 and a frame covering the porous member 18c. The chuck table 18 has a suction channel, not depicted, defined therein that has an end fluidly connected to a suction source, not depicted, such as an ejector disposed outside of the chuck table 18. The other end of the suction channel is fluidly connected to the porous member 18c.

The porous member 18c has an upper surface exposed as the holding surface 18a of the chuck table 18. The upper surface of the porous member 18c is equal in diameter to the workpiece 1 and lies substantially parallel to the X-axis and the Y-axis. A plurality of clamps 18b for securely gripping the annular frame that supports the workpiece 1 in the frame unit are disposed around the chuck table 18.

For holding the workpiece 1 under suction on the chuck table 18, the frame unit that includes the workpiece 1 is placed on the holding surface 18a of the chuck table 18. Then, the suction source is fluidly connected to the porous member 18c via the suction channel by a valve, not depicted, and is actuated to generate and apply a negative pressure through the suction channel and the porous member 18c to the workpiece 1 via the tape affixed to the reverse side 1b of the workpiece 1. The annular frame of the frame unit is secured by the clamps 18b.

The cutting apparatus 2 includes a delivery unit, not depicted, near the opening 4b for delivering the workpiece 1 to the chuck table 18 and a temporary rest mechanism disposed near and laterally of the cassette support table 8 for supporting the workpiece 1 temporarily placed thereon. The temporary rest mechanism includes a pair of guide rails 12 disposed over the opening 4b that are movable toward and away from each other along the X-axis while being kept parallel to each other and the Y-axis, i.e., indexing-feed directions. After having received the workpiece 1 taken out of the cassette 10 by the delivery unit, the guide rails 12 are moved toward each other to grip the workpiece 1 therebetween, thereby aligning the workpiece 1 with a predetermined position. The workpiece 1 thus aligned is pulled up by the delivery unit and delivered to the chuck table 18. Then, the guide rails 12 are moved away from each other, letting the workpiece 1 dropping between the guide rails 12 onto the chuck table 18.

The cutting apparatus 2 further includes a first cutting unit 24a for cutting the workpiece 1 with an annular cutting blade and a second cutting unit 24b for cutting the workpiece 1 with an annular cutting blade. The first cutting unit 24a and the second cutting unit 24b are supported on a portal-shaped support structure 20 disposed on an upper surface of the foundation base 4 astride the opening 4b. The support structure 20 supports on a front surface thereof that faces the viewer of FIG. 2 a first moving unit 22a for moving the first cutting unit 24a along the Y-axis and the Z-axis and a second moving unit 22b for moving the second cutting unit 24b along the Y-axis and the Z-axis. The first moving unit 22a has a Y-axis movable plate 28a, and the second moving unit 22b has a Y-axis movable plate 28b. The two Y-axis movable plates 28a and 28b are slidably mounted on a pair of Y-axis guide rails 26 disposed on the front surface of the support structure 20 and extending along the Y-axis.

A nut, not depicted, is mounted on a reverse side, i.e., a rear surface, facing away from the viewer, of the Y-axis movable plate 28a. The nut is operatively threaded over a Y-axis ball screw 30a rotatably mounted on the front surface of the support structure 20 and extending parallel to the Y-axis guide rails 26. Similarly, another nut, not depicted, is mounted on a reverse side, i.e., a rear surface, facing away from the viewer, of the Y-axis movable plate 28b. The nut is operatively threaded over a Y-axis ball screw 30b rotatably mounted on the front surface of the support structure 20 and extending parallel to the Y-axis guide rails 26. The Y-axis ball screw 30a has an end coupled to a Y-axis stepping motor 32a fixedly mounted on the front surface of the support structure 20. When the Y-axis stepping motor 32a is energized, it rotates the Y-axis ball screw 30a about its central axis, causing the nut threaded thereover to move the Y-axis movable plate 28a along the Y-axis guide rails 26 along the Y-axis. Similarly, the Y-axis ball screw 30b has an end coupled to a Y-axis stepping motor, not depicted, fixedly mounted on the front surface of the support structure 20. When the Y-axis stepping motor is energized, it rotates the Y-axis ball screw 30b about its central axis, causing the nut threaded thereover to move the Y-axis movable plate 28b along the Y-axis guide rails 26 along the Y-axis.

The Y-axis movable plate 28a supports a pair of Z-axis guide rails 34a extending along the Z-axis on a face side thereof, i.e., a front surface, that faces the viewer of FIG. 2, and the Y-axis movable plate 28b supports a pair of Z-axis guide rails 34b extending along the Z-axis on a face side thereof, i.e., a front surface, that faces the viewer of FIG. 2. A Z-axis movable plate 36a is slidably mounted on the Z-axis guide rails 34a, and a Z-axis movable plate 36b is slidably mounted on the Z-axis guide rails 34b.

A nut, not depicted, is mounted on a reverse side, i.e., a rear surface, facing away from the viewer, of the Z-axis movable plate 36a. The nut is operatively threaded over a Z-axis ball screw 38a rotatably mounted on the front surface of the Y-axis movable plate 28a and extending parallel to the Z-axis guide rails 34a. The Z-axis ball screw 38a has an end coupled to a Z-axis stepping motor 40a fixedly mounted on the front surface of the Y-axis movable plate 28a. When the Z-axis stepping motor 40a is energized, it rotates the Z-axis ball screw 38a about its central axis, causing the nut threaded thereover to move the Z-axis movable plate 36a along the Z-axis guide rails 34a along the Z-axis. Similarly, a nut, not depicted, is mounted on a reverse side, i.e., a rear surface, facing away from the viewer, of the Z-axis movable plate 36b. The nut is operatively threaded over a Z-axis ball screw 38b rotatably mounted on the front surface of the Y-axis movable plate 28b and extending parallel to the Z-axis guide rails 34b. The Z-axis ball screw 38b has an end coupled to a Z-axis stepping motor 40b fixedly mounted on the front surface of the Y-axis movable plate 28b. When the Z-axis stepping motor 40b is energized, it rotates the Z-axis ball screw 38b about its central axis, causing the nut threaded thereover to move the Z-axis movable plate 36b along the Z-axis guide rails 34b along the Z-axis.

The first cutting unit 24a is mounted on a lower end portion of the Z-axis movable plate 36a. A camera unit 46a for capturing an image of the workpiece 1 held under suction on the chuck table 18 is also mounted on the lower end portion of the Z-axis movable plate 36a at a position adjacent to the first cutting unit 24a. The second cutting unit 24b is mounted on a lower end portion of the Z-axis movable plate 36b. A camera unit 46b for capturing an image of the workpiece 1 held under suction on the chuck table 18 is also mounted on the lower end portion of the Z-axis movable plate 36b at a position adjacent to the second cutting unit 24b. The first moving unit 22a controls the positions of the first cutting unit 24a and the camera unit 46a along the Y-axis and the Z-axis, whereas the second moving unit 22b controls the positions of the second cutting unit 24b and the camera unit 46b along the Y-axis and the Z-axis. The position of the first cutting unit 24a and the position of the second cutting unit 24b are controlled independently of each other.

The foundation base 4 also has an upwardly open circular opening 4c defined therein at a position across the opening 4b from the opening 4a. The opening 4c houses therein a cleaning unit 48 for cleaning the workpiece 1. The workpiece 1 that has been cut on the chuck table 18 by the first and second cutting units 24a and 24b is delivered to the cleaning unit 48 and cleaned by the cleaning unit 48. After having been cleaned by the cleaning unit 48, the workpiece 1 is delivered to the cassette 10 and stored back in the cassette 10.

The first and second cutting units 24a and 24b will further be described below. FIG. 4 schematically illustrates, in size elevation, the manner in which the conventional edge trimming process is performed on the workpiece 1 by one of the first and second cutting units 24a and 24b. The edge trimming process may be performed by either the first cutting unit 24a or the second cutting unit 24b. In FIG. 4, one of the first and second cutting units 24a and 24b that are identical in structure to each other, referred to as a “cutting unit 24,” is used to perform the edge trimming process. The cutting unit 24 includes a spindle 50 extending along the Y-axis and rotatable about its central axis parallel to the Y-axis and a spindle housing, not depicted, in which a proximal end portion of the spindle 50 is rotatably housed. The spindle housing also houses therein a rotary actuator, not depicted, such as an electric motor coupled to the proximal end portion of the spindle 50. The spindle 50 has a distal end portion exposed out of the spindle housing and supporting an annular cutting blade 56 secured to the spindle 50 by a flange mechanism 52 and a mounting nut 54.

The cutting blade 56 includes a cutting blade of the hub type that has an annular base 58 made of a material such as aluminum and having a central through hole therein and a cutting edge portion, i.e., a grindstone portion, 60 fixed to an outer circumferential edge of the base 58. However, the cutting blade 56 is not limited to the hub type. The cutting edge portion 60 includes countless abrasive grains and a binder, i.e., a bonding matrix, in which the abrasive grains are securely dispersed. For example, the abrasive grains are made of diamond or cubic boron nitride (BN), whereas the binding matrix includes a plated nickel layer, a resin bond, a vitrified bond, or a metal bond. The cutting blade 56, i.e., the cutting edge portion 60, has a thickness depending on the width of the beveled edge on the outer circumferential portion 1c of the workpiece 1, for example. For example, the thickness of the cutting blade 56 should preferably in the range from 0.5 to 5 mm. The cutting blade 56 should preferably have a diameter in the range from 49 to 59 mm. However, the thickness and diameter of the cutting blade 56 are not limited to the numerical ranges referred to above.

When the rotary actuator coupled to the spindle 50 is energized, it rotates the spindle 50 and hence the cutting blade 56 about their central axes. The rotating cutting blade 56 is caused to cut, i.e., incise, into the workpiece 1 held under suction on the chuck table 18, thereby cutting the workpiece 1. At this time, a cutting fluid such as pure water is ejected to the workpiece 1 and the cutting blade 56, removing swarf and frictional heat produced from cutting the workpiece 1 with the cutting blade 56.

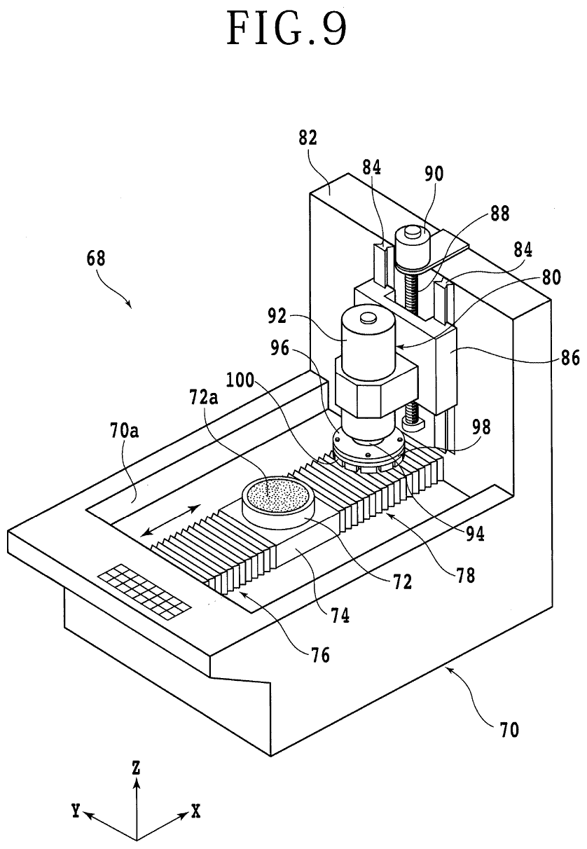

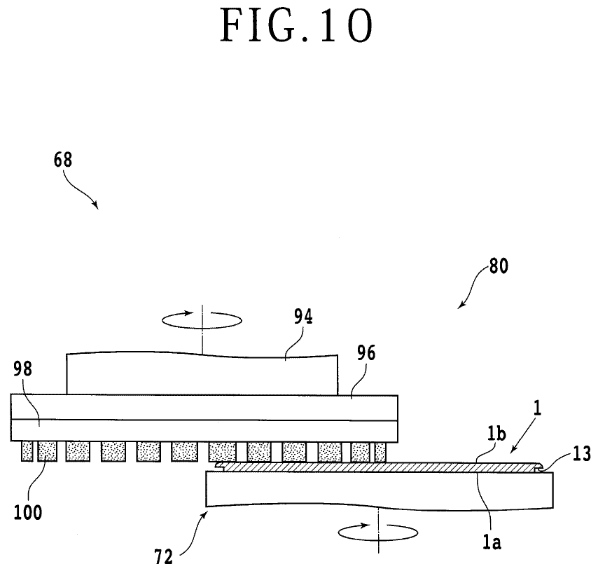

Now, a grinding apparatus that can be used to thin down the workpiece 1 that has been processed by the edge trimming process. FIG. 9 schematically illustrates the grinding apparatus, denoted by 68. FIG. 10 schematically illustrates, in side elevation, partly in cross section, the manner in which the workpiece 1 is ground by the grinding apparatus 68. In FIG. 9, the grinding apparatus 68 is illustrated in reference to a three-dimensional XYZ coordinate system that is similar to the three-dimensional XYZ coordinate system described above with reference to FIG. 2. As illustrated in FIG. 9, the grinding apparatus 68 includes a foundation base 70 that supports various components of the grinding apparatus 68 as described below. The foundation base 70 has an upwardly open rectangular opening 70a defined therein that houses an X-axis movable table 74 on which there is mounted a chuck table 72 for holding the workpiece 1 under suction thereon. The X-axis movable table 74 is movable along the X-axis by an X-axis moving mechanism, not depicted. The X-axis movable table 74 can be moved between and positioned selectively in a loading/unloading area 76 where the workpiece 1 can be placed on and removed from the chuck table 72 and a processing area 78 where the workpiece 1 held under suction on the chuck table 72 is ground.

A porous member having the same diameter as the workpiece 1 is disposed on an upper surface of the chuck table 72 and has an upper surface as a holding surface 72a for holding the workpiece 1 thereon. The chuck table 72 includes a suction channel, not depicted, defined therein that has an end fluidly connected to a suction source, not depicted, and another end fluidly connected to the porous member. When the suction source is actuated, it generates and applies a negative pressure through the suction channel and the porous member to the workpiece 1 on the holding surface 72a of the chuck table 72, thereby holding the workpiece 1 under suction on the chuck table 72. The chuck table 72 is rotatable about a central axis perpendicular to the holding surface 72a.

The grinding apparatus 68 includes a grinding unit 80 disposed above the processing area 78 for grinding the workpiece 1 on the chuck table 72. The grinding unit 80 is supported by an upstanding support wall 82 extending upwardly from a rear end of the foundation base 70. A pair of Z-axis guide rails 84 extending along the Z-axis are mounted on a front surface, facing the viewer of FIG. 9, of the support wall 82. A Z-axis movable plate 86 is slidably mounted on the Z-axis guide rails 84. A nut, not depicted, is mounted on a reverse side, i.e., a rear surface, facing away from the viewer, of the Z-axis movable plate 86. The nut is operatively threaded over a Z-axis ball screw 88 rotatably mounted on the front surface of the support wall 82 and extending parallel to the Z-axis guide rails 84. The Z-axis ball screw 88 has an end coupled to a Z-axis stepping motor 90 mounted on the support wall 82. When the Z-axis stepping motor 90 is energized, it rotates the Z-axis ball screw 88 about its central axis, causing the nut threaded thereover to move the Z-axis movable plate 86 along the Z-axis guide rails 84 along the Z-axis.

The grinding unit 80 for grinding the workpiece 1 on the chuck table 72 is fixedly mounted on a lower portion of a face side, i.e., a front surface, facing the viewer, of the Z-axis movable plate 86. When the Z-axis movable plate 86 is moved along the Z-axis, therefore, the grinding unit 80 is also moved along the Z-axis. The grinding unit 80 includes a spindle 94 extending along the Z-axis and rotatable about its central axis parallel to the Z-axis, a spindle housing 92 in which an upper end portion of the spindle 94 is rotatably housed, and a wheel mount 96 shaped as a circular plate fixed to the lower end of the spindle 94. The spindle housing 92 also houses therein a rotary actuator, not depicted, such as an electric motor, coupled to the spindle 94 for rotating the spindle 94 about its central axis. An annular grinding wheel 98 is fixed to a lower surface of the wheel mount 96. The grinding wheel 98 has a lower surface on which there are disposed an annular array of grindstones 100 each including abrasive grains of diamond that are securely dispersed in a binder.

When the spindle 94 is rotated about its central axis to rotate the grinding wheel 98, the grindstones 100 rotate along an annular track. Then, the grinding unit 80 is lowered by the Z-axis stepping motor 90 to bring the grindstones 100 into abrasive contact with a surface to be ground of the workpiece 1 on the chuck table 72, grinding the workpiece 1. The grinding apparatus 68 also includes a thickness measuring instrument, not depicted, for measuring the thickness of the workpiece 1. The grinding apparatus 68 grinds the workpiece 1 progressively while monitoring the thickness of the workpiece 1 with the thickness measuring instrument, and stops lowering the grinding unit 80 to finish grinding the workpiece 1 when the workpiece 1 has been ground to a predetermined thickness. When the workpiece 1 is ground by the grindstones 100, swarf and frictional heat are generated from the workpiece 1 and the grindstones 100. The grinding apparatus 68 includes a grinding water supply nozzle, not depicted, that supplies grinding water such as pure water to the workpiece 1 and the grindstones 100 while the grindstones 100 are grinding the workpiece 1. The swarf and frictional heat are removed by the grinding water supplied to the workpiece 1 and the grindstones 100.

While the grinding apparatus 68 is grounding and thinning down the workpiece 1, a protective member, not depicted, should be affixed to the face side 1a of the workpiece 1 in order to protect the face side 1a of the workpiece 1. The protective member includes a member shaped as a circular sheet having the same diameter as the workpiece 1, and is made of a material such as a resin. Specifically, the protective member includes a tape-shaped member including an adhesive layer to be secured to the workpiece 1 by way of adhesive bonding and a base layer supporting the adhesive layer. When the protective member is affixed to the face side 1a of the workpiece 1, the face side 1a is kept out of direct contact with the chuck table 72 when the workpiece 1 is ground on the reverse side 1b thereof. Therefore, the face side 1a of the workpiece 1 remains free of damage. The workpiece 1 with the protective member affixed to the face side 1a thereof is placed on and held under suction on the chuck table 72.

When the edge trimming process is performed on the workpiece 1 such as a wafer, the outer circumferential portion 1c of the workpiece 1 is turned into a terrace surface parallel to the face side 1a and a precipitous wall surface rising sharply from an inner circumferential end of the terrace surface. The terrace surface and the wall surface tend to have abrasive grain marks represented by recess and projection surface irregularities left by abrasive grains contained in the cutting edge portion 60 of the cutting blade 56. In addition, the face side 1a of the workpiece 1 is liable to break into chippings near the wall surface.

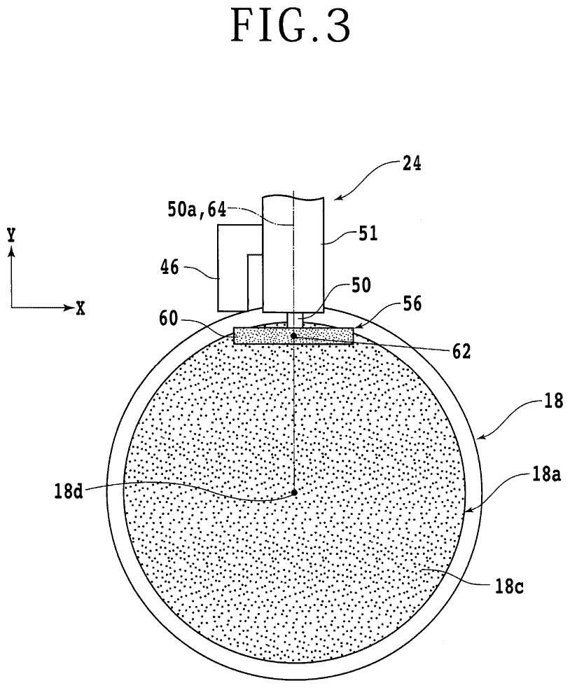

Details of the edge trimming process will be described below. FIG. 3 schematically illustrates, in plan, a positional relation between the chuck table 18 and the cutting blade 56 at the time a conventional edge trimming process is carried out on the workpiece 1. FIG. 4 schematically illustrates, in side elevation, the manner in which the conventional edge trimming process is carried out on the workpiece 1. For illustrative purposes, the workpiece 1 and the clamps 18b are omitted from illustration in FIG. 3, and the clamps 18b are omitted from illustration in FIG. 4. According to the conventional edge trimming process, the orientation of the cutting blade 56 is adjusted such that a line tangential to the circular workpiece 1 is included in the plane of rotation of the cutting edge portion 60 at the incising position where the cutting blade 56 cuts into the outer circumferential portion 1c of the workpiece 1. Stated otherwise, a table rotation axis 18d, i.e., the central axis, about which the chuck table 18 rotates and a blade rotation axis 50a, i.e., the central axis, about which the cutting blade 56 rotates intersect with each other. In other words, the distal end of the spindle 50 of the cutting unit 24 is orientated toward the center of the holding surface 18a.

During the edge trimming process, the chuck table 18 that is holding the workpiece 1 under suction rotates about the table rotation axis 18d and the cutting blade 56 rotates about the blade rotation axis 50a. Therefore, at the incising position where the cutting blade 56 cuts into the outer circumferential portion 1c of the workpiece 1, the direction along which the outer circumferential portion 1c of the workpiece 1 moves and the direction along which the cutting edge portion 60 moves coincide with each other. It is considered that these directions that coincide with each other are responsible for abrasive grain marks represented by recess and projection surface irregularities left by the abrasive grains contained in the cutting edge portion 60 and chippings from the workpiece 1. When the workpiece 1 that has abrasive grain marks and chippings caused by the edge trimming process is subsequently ground, cracks are brought about in the wafer from the abrasive grain marks and the chippings due to impact. The cracks are likely to develop in the workpiece 1 and fragments caused by the abrasive grain marks are apt to be separated and then deposited on the workpiece 1. Furthermore, swarf produced from the workpiece 1 when the workpiece 1 is ground find its way into the abrasive grain marks and remain trapped in the workpiece 1. If the above difficulties occur, then when the workpiece 1 is subsequently divided into device chips, the device chips are highly likely to become poor in quality, or the number of normal device chips fabricated from the workpiece 1 is reduced to the extent that the efficiency with which to fabricate device chips from the workpiece 1 is unduly lowered.

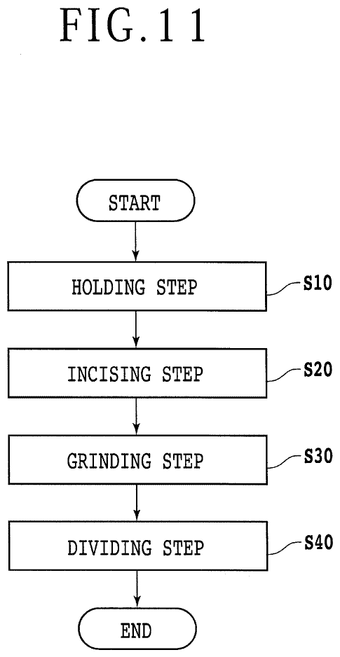

In the method of processing a workpiece according to the present embodiment, an edge trimming process is performed in a manner not to leave deep abrasive grain marks on the terrace surface and wall surface that are formed on the workpiece 1 in the edge trimming process. The method of processing a workpiece according to the present embodiment will be described in detail below. The method of processing a workpiece according to the present embodiment includes an edge trimming process to be performed on the workpiece 1 having on its outer circumferential portion 1c the beveled edge extending from the face side 1a to the reverse side 1b of the workpiece 1. FIG. 11 is a flowchart of the sequence of steps of the method of processing a workpiece according to the present embodiment.

As illustrated in FIG. 11, the method of processing a workpiece according to the present embodiment includes holding step S10, incising step S20, grinding step S30, and dividing step S40. In the method of processing a workpiece according to the present embodiment, holding step S10 is carried out at first. In holding step S10, the workpiece 1 is placed on the holding surface 18a of the chuck table 18 that is rotatable about the table rotation axis 18d that extends across the holding surface 18a, and is held under suction on the holding surface 18a.

Holding step S10 will be described in detail below. In holding step S10, the workpiece 1 is delivered onto the holding surface 18a of the chuck table 18 of the cutting apparatus 2 (see FIG. 2). As the workpiece 1 is integrally combined with the tape and the annular frame, both not depicted, the workpiece 1 is placed on the holding surface 18a with the tape interposed therebetween. At this time, the face side 1a of the workpiece 1 that is opposite the reverse side 1b that is a surface to be ground of the workpiece 1 faces upwardly, and the workpiece 1 is positionally adjusted to keep the center of the workpiece 1 in alignment with the center of the holding surface 18a. Thereafter, the suction source fluidly connected to the chuck table 18 is actuated to hold the workpiece 1 under suction on the chuck table 18. The annular frame that supports the workpiece 1 via the tape is gripped by the clamps 18b.

In the method of processing a workpiece according to the present embodiment, after holding step S10, incising step S20 is carried out to remove a part of the workpiece 1 by cutting a part of the beveled edge from the workpiece 1 with the cutting blade 56. In other words, the edge trimming process is performed.

Incising step S20 will be described in detail below. In incising step S20, while the annular cutting blade 56 including the cutting edge portion 60 on the outer circumferential edge of the annular base 58 is being rotated about the blade rotation axis 50a, the cutting edge portion 60 is forced to cut into the beveled edge of the workpiece 1. At the same time, the chuck table 18 is rotated about the table rotation axis 18d to make one revolution or more. In this manner, the cutting blade 56 cuts off a part of the beveled edge of the workpiece 1, thereby removing a part of the workpiece 1.

Incising step S20 will be described in greater detail below. First, the cutting unit 24 is positionally adjusted to position the cutting edge portion 60 of the cutting blade 56 in the vicinity of an end of the holding surface 18a of the chuck table 18. The spindle 50 starts being rotated about its central axis, rotating the cutting blade 56 about the blade rotation axis 50a at a speed of approximately 30,000 rpm. Then, the cutting blade 56 is lowered to a predetermined heightwise position. The predetermined heightwise position refers to a vertical position where the lowermost point of the cutting edge portion 60 is lower than the face side 1a of the workpiece 1 held under suction on the chuck table 18. More specifically, the predetermined heightwise position refers to a vertical position where the lowermost point of the cutting edge portion 60 is lower than the face side 1a of the workpiece 1 by a depth larger than a final finished thickness that the workpiece 1 is to attain after being ground.

Specifically, the predetermined heightwise position refers to a vertical position where the lowermost point of the cutting edge portion 60 is lower than the face side 1a of the workpiece 1 by a distance in the range from 3 to 800 μm. Stated otherwise, the depth to which the cutting blade 56 cuts into the workpiece 1 in the edge trimming process is in the range from 3 to 800 μm. However, the predetermined heightwise position is not limited to the above numerical range. The lowermost point of the cutting edge portion 60 may alternatively reach a heightwise position lower than the reverse side 1b of the workpiece 1.

For example, the cutting blade 56 is lowered from above the incising position where it is to cut into the outer circumferential portion 1c of the workpiece 1 toward the outer circumferential portion 1c, and then is positioned at the predetermined heightwise position. When the cutting edge portion 60 of the rotating cutting blade 56 comes into abrasive contact with the workpiece 1, the workpiece 1 is cut by the cutting edge portion 60. Alternatively, the cutting blade 56 is lowered to the predetermined heightwise position outside of the outer circumferential portion 1c. Thereafter, the chuck table 18 is moved in a direction parallel to the holding surface 18a toward the cutting blade 56, so that the cutting edge portion 60 is moved to the incising position where it is to cut into the outer circumferential portion 1c of the workpiece 1. At this time, when the cutting edge portion 60 of the rotating cutting blade 56 comes into abrasive contact with the workpiece 1, the workpiece 1 is cut by the cutting edge portion 60.

With the cutting edge portion 60 cutting into the outer circumferential portion 1c at the incising position, the chuck table 18 is rotated about the table rotation axis 18d to make one revolution or more. The cutting blade 56 now cuts the workpiece 1 along the outer circumferential portion 1c thereof, thereby removing a part of the beveled edge from the outer circumferential portion 1c. In this manner, the workpiece 1 is processed in the edge trimming process. The speed at which the chuck table 18 is rotated about the table rotation axis 18d may be in the range from 0.1° per second to 180° per second.

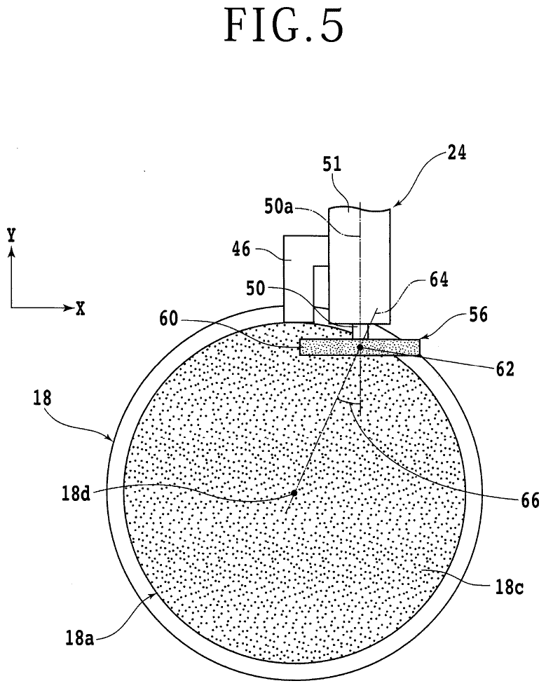

In the method of processing a workpiece according to the present embodiment, while the cutting blade 56 is cutting the beveled edge of the workpiece 1, the table rotation axis 18d and the blade rotation axis 50a do not intersect with each other. FIG. 5 schematically illustrates, in plan, a positional relation between the chuck table 18 and the cutting unit 24 at the time incising step S20 according to an example is carried out, i.e., at the time the cutting blade 56 cuts the beveled edge. In FIG. 5, the workpiece 1 is omitted from illustration for illustrative purposes.

According to the conventional edge trimming process, as illustrated in FIG. 3, the table rotation axis 18d extending generally along the Z-axis intersects with the blade rotation axis 50a. On the other hand, in incising step S20 of the method of processing a workpiece according to the present embodiment, as illustrated in FIG. 5, the table rotation axis 18d extending generally along the Z-axis does not intersect with the blade rotation axis 50a. Therefore, in the incising position where the cutting edge portion 60 cuts into the outer circumferential portion 1c, the direction along which the workpiece 1 moves and the direction along which the cutting edge portion 60 moves do not coincide with each other. Since the workpiece 1 is rotating about its central axis, i.e., the table rotation axis 18d, the orientation of abrasive grain marks formed on the outer circumferential portion 1c in one moment varies greatly from the direction along which the cutting edge portion 60 in a next moment. Consequently, even though abrasive grain marks are formed on the workpiece 1 by the abrasive grains exposed on the outer circumferential edge of the cutting edge portion 60, the abrasive grain marks are immediately polished off by the cutting edge portion 60, planarizing the workpiece 1. As a result, the abrasive grain marks are considered to be reduced or removed from the workpiece 1.

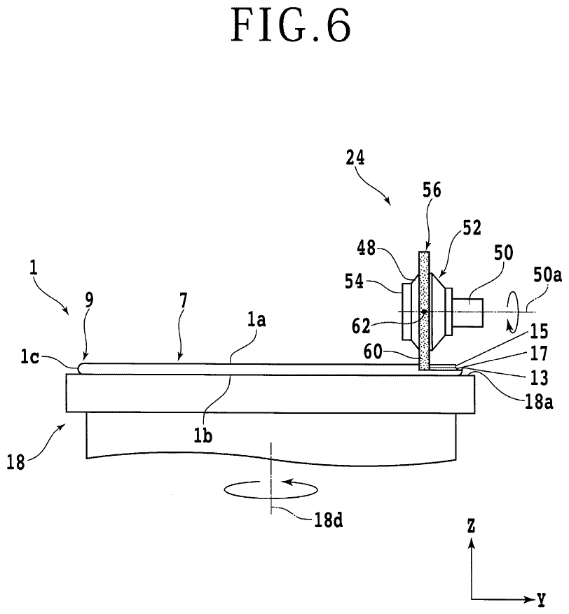

When the edge trimming process is carried out while the table rotation axis 18d and the blade rotation axis 50a are not intersecting with each other, a terrace surface and a wall surface are formed in the vicinity of the outer circumferential portion 1c of the workpiece 1, and so is a curved surface that connects the terrace surface and the wall surface to each other. FIG. 6 schematically illustrates, in side elevation, the chuck table 18 and the cutting unit 24 in incising step S20 according to the example illustrated in FIG. 5. In FIG. 6, the workpiece 1 is also illustrated in side elevation. As illustrated in FIG. 6, in the case where the table rotation axis 18d and the blade rotation axis 50a do not intersect with each other, a curved surface 17 of round shape that reflects the outer circumferential shape of the cutting edge portion 60 of the cutting blade 56 is formed between a terrace surface 13 parallel to the face side 1a and a wall surface 15 perpendicular to the face side 1a on the outer circumferential portion 1c. The curved surface 17 is considered to reinforce the terrace surface 13 and the wall surface 15, making the workpiece 1 with the curved surface 17 less liable to cause cracks and chipping.

Therefore, when the edge trimming process is carried out while the table rotation axis 18d and the blade rotation axis 50a are not intersecting with each other, the quality of device chips fabricated from the workpiece 1 when the workpiece 1 is finally divided becomes higher, or the number of normal device chips fabricated from the workpiece 1 grows, thereby increasing the efficiency with which the device chips are fabricated from the workpiece 1.

The state in which the table rotation axis 18d and the blade rotation axis 50a are not intersecting with each other in incising step S20 will further be described below from another standpoint with reference to FIG. 5. It is assumed that a plane lying parallel to the holding surface 18a of the chuck table 18 and including a center 62 of the cutting edge portion 60 of the cutting blade 56 is established, and the table rotation axis 18d and the center 62 of the cutting edge portion 60 are interconnected by a straight line 64 on the plane. The center 62 of the cutting edge portion 60 refers to a center in the thicknesswise, heightwise, and forward and rearward directions of the cutting edge portion 60. Generally, the center 62 of the cutting edge portion 60 is positioned in a through hole defined centrally in the cutting blade 56 with the distal end of the spindle 50 being inserted in the through hole. As illustrated in FIGS. 5 and 6, the center 62 of the cutting edge portion 60 refers to a point on the blade rotation axis 50a.

The conventional edge trimming process conducted for comparison will be described below. According to the conventional edge trimming process, as illustrated in FIG. 3, the straight line 64 interconnecting the table rotation axis 18d and the center 62 of the cutting edge portion 60 coincides with the blade rotation axis 50a. The straight line 64 and the blade rotation axis 50a form an angle of 0° therebetween. On the other hand, in incising step S20 of the method of processing a workpiece according to the present embodiment, as illustrated in FIG. 5, the straight line 64 interconnecting the table rotation axis 18d and the center 62 of the cutting edge portion 60 do not coincide with the blade rotation axis 50a. The angle, denoted by 66, formed between the straight line 64 and the blade rotation axis 50a is not 0°.

The larger the angle 66 between the straight line 64 and the blade rotation axis 50a becomes, the less likely it is for the abrasive grain marks to remain on the workpiece 1 in the edge trimming process, resulting in reduced cracks developed in the workpiece 1 from the abrasive grain marks. As the angle 66 between the straight line 64 and the blade rotation axis 50a becomes larger, the curved surface 17 interconnecting the terrace surface 13 and the wall surface 15 becomes larger.

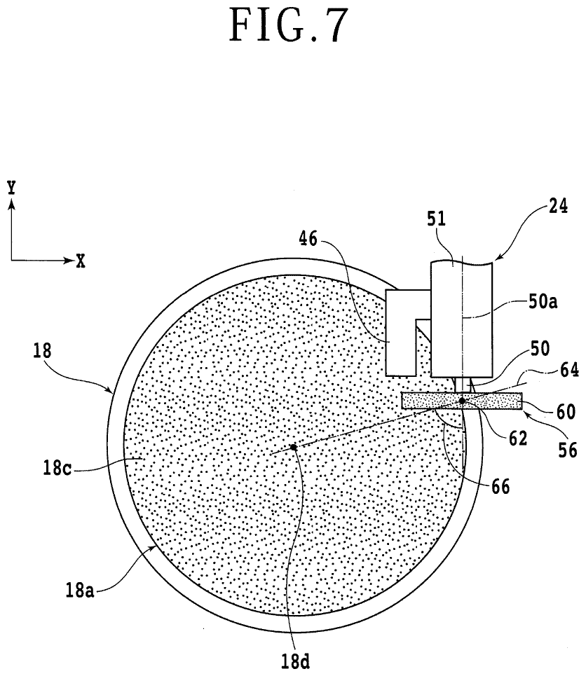

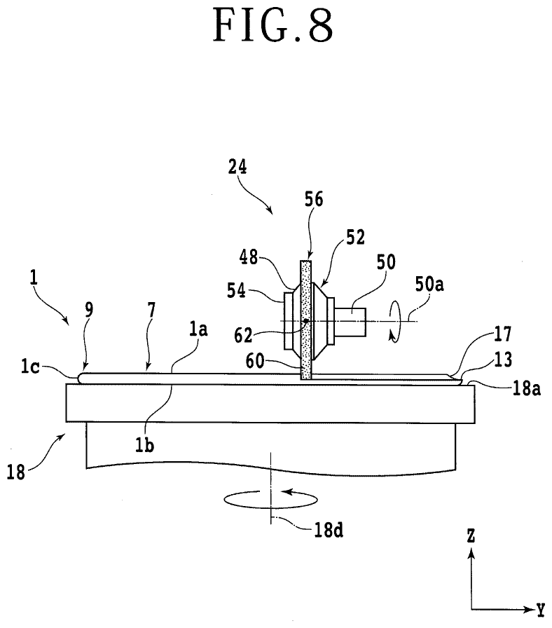

FIG. 7 schematically illustrates, in plan, a positional relation between the cutting unit 24 and the chuck table 18 at the time the cutting blade 56 cuts the beveled edge of the workpiece 1, i.e., at the time incising step S20 according to another example is carried out. In FIG. 7, the angle 66 is larger than the angle 66 in FIG. 5. In FIG. 7, the workpiece 1 is omitted from illustration for illustrative purposes. FIG. 8 schematically illustrates, in side elevation, the chuck table 18 and the cutting unit 24 in incising step S20 according to the other example. In FIG. 8, the workpiece 1 is also illustrated in side elevation. A comparison between FIGS. 6 and 8 indicates that as the angle 66 becomes relatively larger, the curved surface 17 of round shape formed due to the outer circumferential shape of the cutting edge portion 6 is formed in a larger size. Therefore, the larger angle 66 makes the curved surface 17 more effective to reinforce the terrace surface 13 and the wall surface 15.

An experiment conducted to confirm the relation between the angle 66 between the straight line 64 and the blade rotation axis 50a and the size of chippings occurring on the workpiece 1 in the edge trimming process will be described below. In the experiment, the edge trimming process was carried out on a plurality of workpieces 1 each including a silicon wafer having a diameter of 300 mm and a thickness of approximately 780 μm and having a beveled edge on the outer circumferential portion 1c. In the edge trimming process in the experiment, a cutting blade 56 whose cutting edge portion 60 had a thickness of 3 mm and a diameter of 58 mm was used. The cutting blade 56 was rotated at a speed of approximately 30,000 rpm, and the chuck table 18 was rotated at a speed of 3° per second. The cutting blade 56 was forced to cut into the workpieces 1 to an incising depth of 30 μm.

The edge trimming process was carried out on the workpieces 1 under the same conditions except that the straight line 64 and the blade rotation axis 50a formed different angles 66. Specifically, the edge trimming process was carried out with the different angles 66 of 0°, 1°, 2°, 3°, 5°, 10°, 45°, and 90°, respectively, on the workpieces 1. The edge trimming process carried out with the angle 66 of 0° represents the conventional edge trimming process conducted for comparison. After the edge trimming process was performed on the workpieces 1, the ends of the face sides 1a of the respective workpieces 1 were observed and the sizes of chippings formed on the workpieces 1 were measured. As a result, the average size of the chippings formed when the angle 66 was of 0° was 11.5 μm, the average size of the chippings formed when the angle 66 was of 1° was 9.1 μm, the average size of the chippings formed when the angle 66 was of 2° was 5.4 μm, and the average size of the chippings formed when the angle 66 was of 3° was 4.4 μm. When the angle 66 was of 5° or larger, no chippings of significant sizes were formed on the workpieces 1. Stated otherwise, the average size of the chippings was of 0.0 μm when the angle 66 was of 5° or larger.

It can be understood from these experimental results that chippings formed on the workpiece 1 in the edge trimming process are small in size when the angle 66 is larger than 0°. Particularly, it can be seen that when the angle 66 is of 5° or larger, no chippings of significant sizes are formed on the workpiece 1. When the angle 66 exceeds 90°, the tendency to produce chippings until the angle 66 reaches 180° is considered to be the same as the tendency to produce chippings when the angle 66 reaches 0° from 90°. This is because the cutting edge portion 60 of the cutting blade 56 acts on the workpiece 1 in similar manners when the angle 66 is smaller than 90° as a boundary and when the angle 66 is larger than 90° as the boundary. In other words, it is considered that no significant chippings occur in the edge trimming process until the angle 66 exceeds 175° and the average size of chippings increases until the angle 66 reaches 180°.

Consequently, it is preferable that the angle 66 formed between the straight line 64 interconnecting the table rotation axis 18d and the center 62 of the cutting edge portion 60 of the cutting blade 56 on the plane lying parallel to the holding surface 18a and the center 62 of the cutting edge portion 60 and including the center 62 of the cutting edge portion 60 and the blade rotation axis 50a be not either 0° or 180°. More preferably, the angle 66 should be in the range from 5° to 175°. When the edge trimming process is carried out on the workpiece 1 by performing incising step S20 described above, the workpiece 1 is less likely to cause abrasive grain marks and chippings. Therefore, the device chips fabricated from the workpiece 1 by subsequently thinning down and dividing the workpiece 1 are high in quality.

In the method of processing a workpiece according to the present embodiment, grinding step S30 may then be carried out. Grinding step S30 will be described below. In grinding step S30, the workpiece 1 is ground and hence thinned down on the reverse side 1b to a predetermined finished thickness. Grinding step S30 is carried out by the grinding apparatus 68 illustrated in FIG. 9. In preparation for grinding step S30, the tape affixed to the reverse side 1b of the workpiece 1 is peeled off. In addition, a tape-shaped protective member, not depicted, may be affixed to the face side 1a of the workpiece 1 to protect the devices 5 constructed in the demarcated areas of the face side 1a.

In grinding step S30, the face side 1a of the workpiece 1 faces downwardly and the reverse side 1b thereof, which is a surface to be ground, faces upwardly. Then, the workpiece 1 is placed on the holding surface 72a of the chuck table 72 and held under suction on the chuck table 72. Then, the chuck table 72 is moved to the processing area 78 (see FIG. 9). Thereafter, the spindle 94 is rotated about its central axis to rotate the grinding wheel 98, rotating the grindstones 100 along the annular track. Then, the grinding unit 80 starts being lowered to bring the bottom surfaces of the rotating grindstones 100 into abrasive contact with the reverse side 1b of the workpiece 1, thereby starting to grind the workpiece 1. FIG. 10 schematically illustrates grinding step S30 in cross section.

In grinding step S30, the thickness measuring instrument, not depicted, monitors the thickness of the workpiece 1. When it is confirmed that the monitored thickness of the workpiece 1 has reached the predetermined finished thickness, the grinding unit 80 finishes being lowered, ending the grinding of the workpiece 1. Since no beveled edge remains on the outer circumferential portion 1c of the workpiece 1 that has been ground, there is no knife-edge shape occurring in the cross-sectional shape of the workpiece 1, and hence, the workpiece 1 is not likely to be damaged due to a knife-edge shape. After grinding step S30, dividing step S40 may be performed on the workpiece 1 to divide the workpiece 1 along the projected dicing lines 3 into individual device chips. The workpiece 1 may be divided by the cutting apparatus 2 illustrated in FIG. 2, for example. In dividing step S40, the cutting blade 56 of the cutting apparatus 2 cuts the workpiece 1 along the projected dicing lines 3, dividing the workpiece 1 therealong into individual device chips including the respective devices 5.

As described above, with the method of processing a workpiece according to the present embodiment, the workpiece 1 is restrained from giving rise to abrasive grain marks and chippings according to the edge trimming process carried out in incising step S20. In other words, the edge trimming process is carried out with high quality. Therefore, the device chips fabricated from the workpiece 1 by dividing the workpiece 1 are high in quality, or the number of normal device chips fabricated from the workpiece 1 is increased, increasing the efficiency with which to fabricate device chips from the workpiece 1.

The present invention is not limited to the above preferred embodiment, and various changes and modifications may be made therein. For example, according to the above embodiment, as illustrated in FIG. 6, the terrace surface 13 and the wall surface 15 are formed on the outer circumferential portion 1c of the workpiece 1 in incising step S20. However, the present invention is not limited to these details of incising step S20. In incising step S20, both the terrace surface 13 and the wall surface 15 do not need to be formed on the workpiece 1, and instead either one of them or neither of them may be formed. For example, in incising step S20 illustrated in FIG. 8, no wall surface 15 may be formed on the outer circumferential portion 1c of the workpiece 1, and the curved surface 17 may be formed on the face side 1a of the workpiece 1. Alternatively, for example, in incising step S20, no terrace surface 13 may be formed on the outer circumferential portion 1c of the workpiece 1, and the curved surface 17 may be joined to the outer circumference of the workpiece 1.

Furthermore, in incising step S20, no clear boundary may be present between the curved surface 17 formed on the workpiece 1 and the wall surface 15 or the terrace surface 13. In a case where the terrace surface 13 and the wall surface 15 that are not directly joined to each other but are joined to each other through the curved surface 17, the curved surface 17 can reinforce the workpiece 1.

According to the above embodiment, in incising step S20, the cutting blade 56 does not change its position while the chuck table 18 is rotating. However, the present invention is not limited to this feature of incising step S20. According to the above embodiment, furthermore, the edge trimming process is carried out on the entire circumference of the workpiece 1 by causing the chuck table 18 to make one revolution. However, the present invention is not limited to this feature of incising step S20. For example, while the cutting blade 56 is cutting into the outer circumferential portion 1cof the workpiece 1, the cutting blade 56 may be moved parallel to the holding surface 18a toward the center of the workpiece 1, or the chuck table 18 may make two revolutions or more. Stated otherwise, the cutting blade 56 may cut into the workpiece 1 gradually radially inwardly from the outer circumferential portion 1c. For example, in incising step S20, while the chuck table 18 is rotating to make five revolutions, the cutting blade 56 may cut into the workpiece 1 gradually radially inwardly toward the center thereof from the outer circumferential portion 1c. If the edge trimming process is gradually performed in this manner, then since the cutting edge portion 60 of the cutting blade 56 cuts off a relatively small amount of material from the workpiece 1 per unit time, the load imposed on the cutting edge portion 60 of the cutting blade 56 is reduced.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A method of processing a workpiece having a beveled edge on its outer circumferential portion by performing an edge trimming process on the outer circumferential portion thereby to cut off a part of the outer circumferential portion, the method comprising:
a holding step of placing the workpiece on a holding surface of a chuck table that is rotatable about a table rotation axis perpendicular to the holding surface and holding the workpiece on the chuck table; and
after the holding step, an incising step of forcing a cutting edge portion of an annular cutting blade to cut into the beveled edge of the workpiece while the cutting blade is rotating about a blade rotation axis, and causing the chuck table to make at least one revolution about the table rotation axis, thereby cutting into the beveled edge with the cutting blade along an entire outer circumference of the workpiece to cut off a part of the workpiece, wherein,
while the cutting blade is cutting into the beveled edge of the workpiece in the incising step, the table rotation axis and the blade rotation axis do not intersect with each other.

2. The method of processing a workpiece according to claim 1, wherein
while the cutting blade is cutting into the beveled edge of the workpiece in the incising step, an angle formed between a straight line interconnecting the table rotation axis and a center of the cutting edge portion of the cutting blade on a plane lying parallel to the holding surface of the chuck table and including the center of the cutting edge portion of the cutting blade and the blade rotation axis is in a range from 5° to 175°.
